(19) United States
(12) Patent Application Publication
(10) Pub. No.: US 2003/0003625 A1
(43) Pub. Date: Jan. 2, 2003

(54) Leadframe pedestals for uniform die attach

(76) Inventors: Barbara D. Kotzias, Orlando, FL (US); William C. Finley, Windermere, FL (US)

Correspondence Address: CHRISTIE, PARKER & HALE, LLP, 350 WEST COLORADO BOULEVARD, SUITE 500, PASADENA, CA, 91105, US

(21) Appl. No.: 09/896,452

(22) Filed: Jun. 29, 2001

(51) Int. Cl. H01L 21/44

(52) U.S. Cl. 438/112; 257/735

(57) ABSTRACT

A leadframe assembly including a semiconductor die coupled to a mounting area includes at least three pedestals extending above the surface of the mounting area. The pedestals are of the same height and contact the bottom surface of the semiconductor die which is joined to the mounting area by an adhesive formed continuously over the mounting area. The method for forming the leadframe includes forming the pedestals by stamping a malleable leadframe or joining separately formed pedestals to the mounting area. The method further provides for forming an adhesive on the mounting area and joining the semiconductor die to the leadframe such that the adhesive advantageously extends along the sides of the semiconductor die.

### FIELD OF THE INVENTION

The present invention relates, most generally, to semiconductor products and packages. More particularly, the invention relates to leadframes upon which a semiconductor device may be mounted, and to methods for forming the leadframe and joining the semiconductor device to the leadframe.

### BACKGROUND OF THE INVENTION

Electronic circuit packages including a plurality of semiconductor chips are widely used in a variety of well-known applications from computers to computer controls of a wide variety of devices, for example, automobiles and home appliances, among others. Electronic circuit packages for complex systems are typically comprised of several interconnected semiconductor chips which may be integrated circuits or various other semiconductor devices. The integrated circuits and other semiconductor devices are usually made from a semiconductor material such as silicon, gallium arsenide, or indium phosphide and may be collectively referred to as semiconductor chips. A semiconductor chip may be considered a shaped and processed semiconductor die which is a sawed or otherwise machined piece of semiconductor substrate which includes a semiconductor device. The semiconductor chips are mounted in packages which are then mounted on printed circuit boards or the like. Packages including integrated circuit chips or other semiconductor devices typically have numerous external pins which are mechanically attached by solder or a variety of other known techniques, to conductive patterns on the printed circuit board.

Typically, the packages on which these semiconductor chips are mounted, include a substrate or other chip mounting apparatus. One example of such a substrate is a leadframe. Leadframes typically include numerous external pins for electrical coupling to printed circuit boards and the like. In addition to the numerous external pins, leadframes also typically include an area on which the semiconductor chip is mounted. The semiconductor chips may be attached to the leadframe by use of adhesives, soldering, or other techniques. After the semiconductor chip is mounted on the leadframe, a wire bonding process is typically used to connect the integrated circuits or other semiconductor components on the chips to the leadframe and therefore to the other components in the electronic circuit package. The wire bonding processing includes joining a wire, typically under 40 microns in diameter, to bond pads formed on the upper surface of the chip. The bond pads may be on the order of 50 microns in diameter and therefore the alignment between the bond pad and the wire being bonded, is quite critical. In addition to the tight tolerance requirements along the x,y plane of the chip surface, wire bonding tools include a similarly precise alignment requirement in the z direction. This is so to avoid punching through the metal formed on the bond pad or failing to contact the bond pad and bond the wire thereto. As such, it can be understood that it is critical to maintain all portions of the top surface of the chip at the same, known height. Alternatively stated, it is critical to maintain the semiconductor chip level with the mounting surface of the leadframe since the wire bonding apparatus typically references the leadframe when performing the wire bonding operation. Furthermore, it is critical to initially mount the chip level with the mounting surface of the leadframe because attempts to re-position and level the chip after the initial mounting, often result in damage to the chip. When chips are mounted on leadframes, it is equally important to assure that the adhesive, solder or other bonding material is free of voids in the region between the chip and the mounting surface of the leadframe. Voids in the adhesive or solder between the chip and the leadframe, result in poor thermal contact and poor thermal conductivity. This is especially troublesome in arrangements in which the leadframe acts as a heat sink to draw heat from the functioning integrated circuit device on the chip. Poor thermal conductivity from the chip can result in overheating and device failure.

It can be therefore understood that it is desirable to mount a chip on a leadframe such that the adhesive joining the chip to the leadframe is uniform and continuous in the region between the chip and the mounting surface of the leadframe. It is also desirable to mount the chip on the leadframe such that the top, exposed surface of the chip is parallel to the mounting surface of the leadframe as originally mounted.

### SUMMARY OF THE INVENTION

To achieve these and other goals, and in view of its purposes, the present invention provides a method for joining a semiconductor die to a leadframe comprising the steps of forming a leadframe having a mounting area for receiving the semiconductor die, and forming at least three pedestals raised above the leadframe surface in the mounting area. The method further provides for introducing an adhesive material onto the mounting area, the adhesive including an average thickness being at least as great as the pedestals, and joining the semiconductor die to the mounting area of the leadframe such that the semiconductor die contacts each of the pedestals and the adhesive material.

The present invention also provides the assembly including the semiconductor die attached to the surface of a leadframe by an adhesive, in which the leadframe includes at least three pedestals of substantially the same pedestal height extending from the leadframe surface and in which the semiconductor die contacts each of the pedestals and the adhesive.

### BRIEF DESCRIPTION OF THE DRAWING

The invention is best understood from the following detailed description when read in conjunction with the accompanying drawing. It is emphasized that, according to common practice, the various features of the drawing are not to scale. On the contrary, the dimensions of the various features are arbitrarily expanded or reduced for clarity. Included in the drawing are the following figures.

FIG. 1 is a plan view showing an exemplary die mount area of a leadframe according to the present invention;

FIG. 2 is a plan view showing another exemplary die mount area of a leadframe according to the present invention;

FIG. 3A is a perspective view of an exemplary leadframe pedestal according to the present invention;

FIG. 3B is a perspective view of another exemplary leadframe pedestal of the present invention;

FIG. 3C is a perspective view of yet another exemplary leadframe pedestal according to the present invention;

FIG. 4 is a cross sectional view of exemplary leadframe pedestals protruding above the mounting surface of a leadframe according to the present invention;

FIGS. 5-7 show an exemplary process sequence used to join a semiconductor chip to an exemplary leadframe according to the present invention. FIG. 5 is a side view showing an exemplary leadframe according to the present invention;

FIG. 6 shows the leadframe shown in FIG. 5 after an adhesive has been added, and showing a semiconductor die positioned to be attached thereto; and

FIG. 7 is a side view showing a semiconductor die attached to an exemplary leadframe according to the present invention.

Like numerals denote like features through the specification and figures.

### DETAILED DESCRIPTION OF THE INVENTION

The present invention provides for forming a leadframe having a mounting area to which a semiconductor die may be attached. A semiconductor die may alternatively be referred to as a semiconductor chip. More particularly, a semiconductor chip may be considered a shaped and processed semiconductor die which is ready for mounting. Hereinafter, the expression semiconductor die will be used to describe the various embodiments of the invention. It should be understood, however, that the terms semiconductor die and semiconductor chip are typically used interchangeably. The leadframe of the present invention includes at least three pedestals of substantially the same height, formed in the mounting area. The pedestals may be formed by various means and may be formed as separate pieces and joined to the surface of the leadframe in the mounting area, or the pedestals may be protrusions of the leadframe itself. The present invention covers the method for joining a semiconductor die to the mounting area of the leadframe using an adhesive such as an epoxy or solder, and the present invention also provides the assembly formed including the semiconductor die mounted on the novel leadframe.

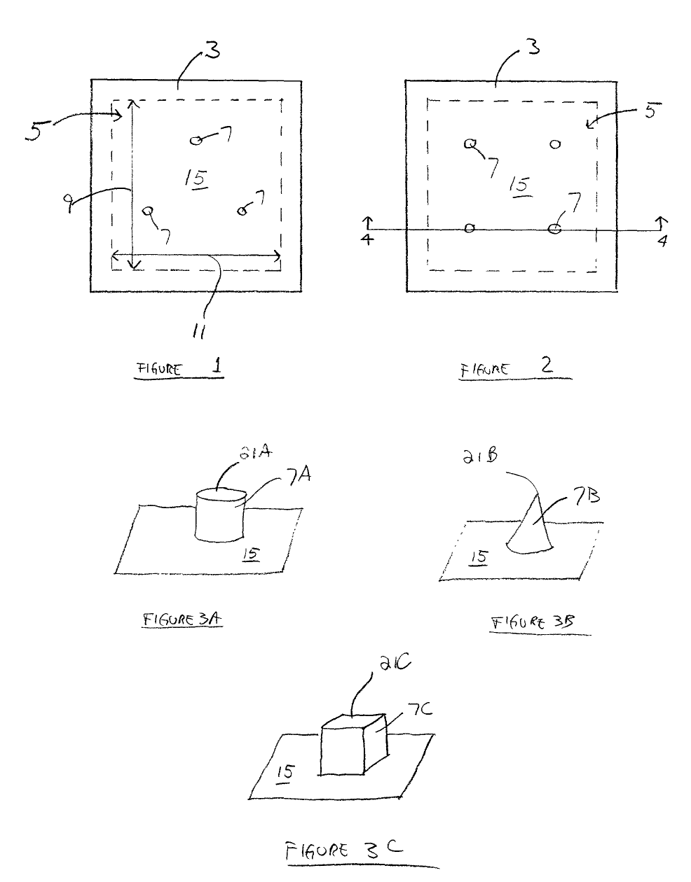

Now turning to the figures, FIG. 1 shows leadframe 3 including die attach or mounting area 5. It should be understood that leadframe 3 also includes a plurality of external pins which extend from the portion of the leadframe shown in FIG. 1 and are used to physically and electrically couple the leadframe to a printed circuit board or the like. For clarity, only the portion of the leadframe including mounting area 5 will be shown. The external pins, which may be arranged in various arrangements, are not shown. Leadframe 3, including the external pins, is a generally flat member. Mounting area 5 includes surface 15 which is substantially planar in the preferred embodiment. Mounting area 5 includes lateral dimensions 9 and 11. Dimensions 9 and 11 of mounting area 5 are typically the dimensions of the semiconductor die to be joined to mounting area 5. Although shown as being substantially square, mounting area 5 may be rectangular or may take on other shapes according to various other exemplary embodiments. Lateral dimensions 9 and 11 may each range from 16 mils to 1 inch in an exemplary embodiment, but other dimensions may be used alternatively. Leadframe 3 may be formed of various materials and in an exemplary embodiment may be formed of a malleable, bendable material so that the external pins of the leadframe (not shown) may be easily positioned and maneuvered when being joined to printed circuit boards and the like. In an exemplary embodiment, leadframe 3 may be formed of copper, nickel-plated copper, or other materials. According to another exemplary embodiment, leadframe 3 may be formed of a rigid, non-malleable material. Mounting area 5 includes substantially planar surface 15 and in an exemplary embodiment, leadframe 3 may be formed of copper and portions of the leadframe including surface 15 of mounting area 5, may have gold or nickel electroplated thereon. Mounting area 5 includes three exemplary pedestals 7 in the exemplary embodiment shown in FIG. 1.

FIG. 2 shows another exemplary embodiment similar to FIG. 1 but in which mounting area 5 includes four exemplary pedestals 7. According to various other exemplary embodiments, mounting area 5 may include various arrangements of at least three pedestals 7. Pedestals 7 are arranged within mounting area 5 so as to evenly bear the weight of the die which will be joined to mounting area 5. Pedestals 7 are arranged to support and balance the die to be mounted in the mounting area and to maintain the die level and parallel to mounting surface 15, which is substantially flat or planar, when the die is initially joined to leadframe 3. Since surface 15 of mounting area 5 is a planar surface and since the semiconductor die to be joined to mounting area 5 is flat and includes a planar upper surface, pedestals 7 include the same pedestal height so that when a semiconductor die is joined to mounting area 5 and contacts each of pedestals 7, the upper surface of the semiconductor die will be substantially parallel to surface 15 of mounting area 5 of leadframe 3.

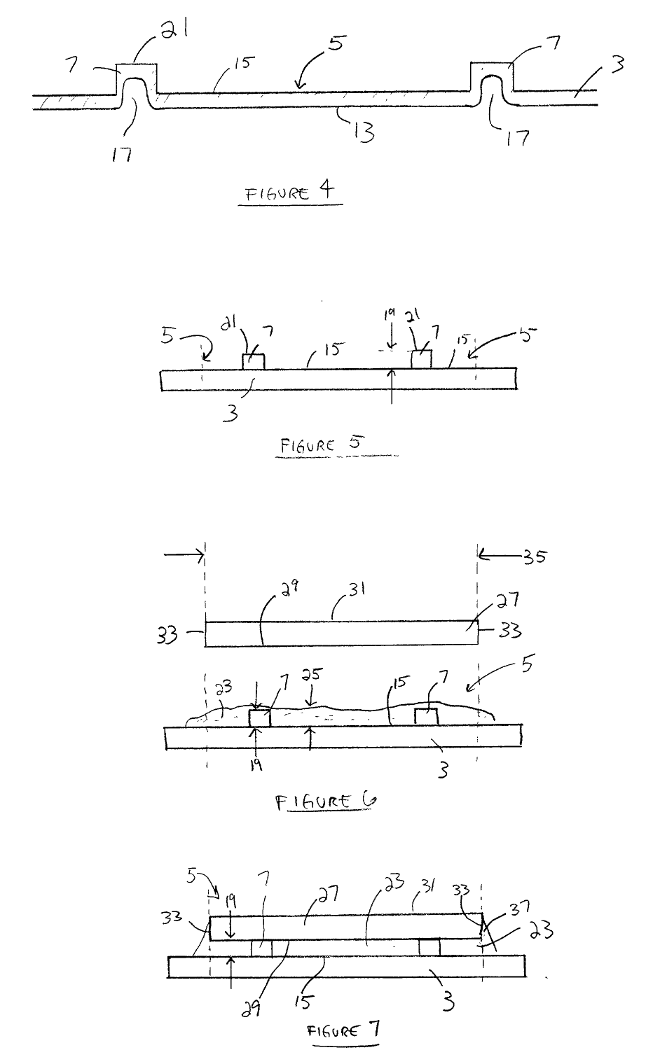

The pedestals may take on various shapes. Exemplary pedestal shapes are shown in FIGS. 3A-3C. The pedestals extend above planar surface 15. According to one exemplary embodiment, the pedestals may be formed separately and joined to surface 15. According to another exemplary embodiment, the pedestals may be formed by stamping the leadframe to cause protrusions to extend from surface 15 and which are therefore integrally formed of leadframe 3. Exemplary pedestal 7A, shown in FIG. 3A, is substantially cylindrical and includes top surface 21A. Exemplary pedestal 7B, shown in FIG. 3B, is substantially conical in shape and includes apex 21A which forms the top surface of exemplary pedestal 7B. FIG. 3C shows exemplary pedestal 21C which is an orthogonal polygon. Pedestal 7C includes top surface 21C. In the preferred embodiment, the three or more pedestals which are formed in mounting area 5, will be of the same shape. The three or more pedestals which appear in mounting area 5 will include the same pedestal height. In an exemplary embodiment, the pedestal height for each of the pedestals which appear in mounting area 5, may range from 1-2 mils, but other pedestal heights may be used alternatively. The top surface of the pedestal, which is adapted to contact the lower surface of the mounted semiconductor die, may be substantially a point such as apex 21 B shown in FIG. 3B, or, such as for the embodiments shown in FIG. 3A and FIG. 3C, may include top surfaces 21A and 21C, respectively, which may include an area ranging from 490 micron² to 2000 micron², but other areas may be used according to various other exemplary embodiments.

According to one exemplary embodiment, pedestals 7 may be formed of a non-deformable material and joined to surface 15 of mounting area 5. According to the exemplary embodiment, pedestals 7 may be formed and joined to mounting area 5 using conventional methods. According to another exemplary embodiment in which mounting area 5 of leadframe 3 is formed of a malleable material, the pedestals may be formed by stamping mounting area 5 of leadframe 3, such as shown in FIG. 4.

Now turning to FIG. 4, pedestals 7 are formed by stamping and extend above planar surface 15. Pedestals 7 are thus integrally formed of the same malleable material which forms leadframe 3. Pedestals 7 are raised above surface 15 and include indentations 17 formed by the stamping process on the opposite side of leadframe 3. The stamping process includes mechanically deforming leadframe 3 by applying a sudden mechanical force to underside 13 of leadframe 3 in mounting area 5. In the cross-sectional view shown in FIG. 4, pedestals 7 include top surface 21 and may be box-shaped or cylindrical in shape, but other pedestal configurations may be used according to other exemplary embodiments.

FIG. 5 shows a side view of exemplary pedestals 7 formed over surface 15 of leadframe 3 within mounting area 5. Each of pedestals 7 includes the same pedestal height 19. Pedestal 7 may be formed as an integral part of leadframe 3 or they may be formed separately and joined to surface 15. FIGS. 5-7 illustrate the sequence of process operations which together constitute a method for joining a semiconductor die to leadframe 3 such that the semiconductor die contacts top surfaces 21 of respective pedestals 7. Adhesive material 23 may be formed on leadframe 3 using conventional methods.

FIG. 6 shows the arrangement shown in FIG. 5 after adhesive material 23 has been formed over leadframe 3. Adhesive material 23 may be an epoxy such as Ablestick, a commercially available epoxy, or various other exemplary epoxies and adhesives may be used. Thickness 25 of adhesive material 23 is chosen to be at least as great as height 19 of pedestals 7. According to the preferred embodiment, adhesive material 23 is formed over the entirety of mounting area 5 and average thickness 25 is chosen to be sufficient that when a die is mounted in mounting area 5, adhesive 23 will be void-free and continuous within mounting area 5. Semiconductor die 27 is also shown in FIG. 6 positioned over mounting area 5 of leadframe 3. Semiconductor die 27 includes top surface 31, bottom surface 29, and sides 33. Semiconductor die 27 includes width 35 which is substantially the same as the width of mounting area 5, in the preferred embodiment. Semiconductor die 27 will advantageously have approximately the same lateral dimensions as mounting area 5. Semiconductor die 27 is substantially flat and includes top surface 31 and bottom surface 29 being substantially parallel to each other. Semiconductor die 27 will typically be rectangular or square in shape and may include lateral dimensions ranging from 16 mils to 1 inch, but may include other lateral dimensions according to other exemplary embodiments. According to one exemplary embodiment, semiconductor die 27 may be substantially square and may include lateral dimensions of 16×16 mils. Semiconductor die 27 may be formed of silicon, gallium arsenide, indium phosphide, or other semiconductor materials. Semiconductor die 27 may be formed of various other ceramic materials according to various exemplary embodiments. According to another exemplary embodiment, semiconductor die 27 may be formed of an insulating material such as sapphire. Top surface 31 includes a semiconductor device formed thereon. In an exemplary embodiment, the semiconductor device may be an integrated circuit. According to other exemplary embodiments, other semiconductor devices such as transistors, resistors, capacitors, and waveguide devices may be formed on top surface 31. Semiconductor die 27 may be polished and finished in preparation for mounting on leadframe 3, using conventional methods. Semiconductor die 27 is grasped, positioned, and eventually joined to leadframe 3 using conventional die attach manufacturing tools. After semiconductor die 27 is positioned over mounting area 5 of leadframe 3 as shown in FIG. 6, semiconductor die 27 is joined to mounting area 5 by bringing bottom surface 29 of semiconductor die 27 into contact with top surfaces 21 of pedestals 7 such as shown in FIG. 7.

According to an exemplary embodiment, and depending upon the epoxy or other adhesive material used, adhesive material 23 may be heated so that it is deformable and contours to the bottom surface 29 of semiconductor die 27 when the components are joined to one another. According to other exemplary embodiments, adhesive material 23 may be deformable at room temperature and may not require heating.

According to yet another exemplary embodiment, adhesive material 23 may be a solder material heated to flow and to accommodate semiconductor die 27 being joined to leadframe 3. In an exemplary embodiment, the solder material may be J-alloy, a silver alloy, or it may be a 5/95 tin/lead eutectic, but other tin/lead eutectics may be used alternatively.

After the components are joined, such as shown in FIG. 7, adhesive material 23 is substantially continuous within mounting area 5 and adheres to each of bottom surface 29 and surface 15 of leadframe 3. According to an exemplary embodiment in which a thermally-curable epoxy is used, the epoxy may be heated to thermally cure the epoxy at this stage. The assembly is characterized by an absence of voids in the mounting area 5. Original thickness 25 of adhesive material 23 is chosen such that, when the components are joined, a portion 37 of adhesive material 23 extends along sides 33 of semiconductor die 27. In an exemplary embodiment, portion 37 of adhesive material 23 may extend upward along 50% to 90% of sides 33, to ensure good bonding. Top surface 31 and bottom surface 29 of semiconductor die 27 are each substantially parallel to surface 15 of mounting area 5 of leadframe 3. In this manner, bond pads (not shown) formed on top surface 31 are at the same height relative to surface 15 and can be reliably wire-bonded using a wire bonding tool which uses surface 15 of leadframe 3 as a reference surface. Because pedestals 7 include the same pedestal height 19, semiconductor die 27 is level with surface 15 as mounted, and does not require additional mechanical maneuvering. Since adhesive material 23 is continuous and uniform within mounting area 5, good thermal conductivity is achieved between semiconductor die 27 and leadframe 3 and therefore leadframe 3 can reliably act as a heat sink as necessary.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. For example, various numbers of pedestals may be used in the mounting area and they may be arranged in various configurations.

Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents described in the future, i.e., any elements developed that perform the same function, regardless of structure. The scope of the present invention, therefore, is not intended to be limited to the exemplary embodiments shown and described herein. Rather, the scope and spirit of the present invention is embodied by the appended claims.

What is claimed is:

1. A method for joining a semiconductor die to a leadframe comprising the steps of:
providing a semiconductor die and a leadframe;
forming at least three pedestals raised above a surface of said leadframe in a mounting area adapted for receiving said semiconductor die attached thereto, each of said pedestals having substantially the same pedestal height;
introducing an adhesive material onto said mounting area, said adhesive material including an average thickness being at least as great as said pedestal height; and
joining said semiconductor die to said mounting area such that said semiconductor die contacts each of said pedestals and said adhesive material.

2. The method as in claim 1, further comprising the step of heating to urge said adhesive material to deform and in which said step of joining includes urging said adhesive material to solidify.

3. The method as in claim 1, in which said adhesive material comprises an epoxy.

4. The method as in claim 1, in which said adhesive material comprises a thermally curable epoxy and said step of joining includes heating to cure said epoxy.

5. The method as in claim 1, in which said pedestals each include a height within the range of 1-2 mils.

6. The method as in claim 1, wherein said leadframe is formed of a malleable material and said step of forming comprises mechanically stamping said leadframe to form said pedestals as integral portions of said leadframe which protrude from said surface.

7. The method as in claim 1, in which each of said pedestals includes a shape being one of cylindrical and conical.

8. The method as in claim 1, in which said step of providing includes providing said semiconductor die having a top including a semiconductor device formed thereon, sides, and a bottom for contacting said pedestals, and in which said step of introducing includes introducing a deformable adhesive material to a sufficient thickness such that said step of joining urges portions of said adhesive material to extend at least partially along said sides of said semiconductor die when said bottom contacts said pedestals.

9. The method as in claim 1, in which said semiconductor die includes an integrated circuit formed on a top surface thereof, and said step of joining includes joining a bottom surface of said die to said leadframe such that said bottom surface contacts each of said pedestals.

10. A method for joining a semiconductor chip to a leadframe comprising the steps of:
providing a leadframe and a semiconductor chip;
forming at least three pedestals raised above a surface of said leadframe in a mounting area adapted for receiving said semiconductor chip attached thereto, each of said pedestals having substantially the same pedestal height;
introducing a viscous solder material onto said mounting area; and
joining said semiconductor chip to said mounting area of said leadframe such that said semiconductor chip contacts each of said pedestals and said solder.

11. An assembly comprising a semiconductor die attached to a surface of a leadframe by an adhesive, said leadframe including at least three pedestals one of protruding from and formed over said surface, each of said pedestals having substantially the same pedestal height, and said semiconductor die contacting each of said pedestals.

12. The assembly as in claim 11, in which said pedestal height lies within the range of 1-2 mils.

13. The assembly as in claim 11, in which said pedestals each include a top portion which contacts said semiconductor die and said top portion includes an area within the range of 490 micron² and 2000 micron².

14. The assembly as in claim 11, in which each of said pedestals are conical in shape and include a base coincident with said surface and an apex which contacts said semiconductor die.

15. The assembly as in claim 11, in which said semiconductor die includes an area which lies within the range of 256 mils² to 1 inch².

16. The assembly as in claim 11, wherein said pedestals each comprise raised portions of said leadframe.

17. The assembly as in claim 11, wherein each of said pedestals are discrete members joined to said surface.

18. The assembly as in claim 11, wherein said leadframe is formed of copper.

19. The assembly as in claim 11, wherein said adhesive comprises an epoxy.

20. The assembly as in claim 11, wherein said pedestals are substantially cylindrical in shape and include substantially flat tops which contact said semiconductor die.

21. The assembly as in claim 11, in which said semiconductor die includes an integrated circuit formed thereon, an opposed bottom surface contacting said adhesive and said pedestals and facing said leadframe, and sides, and said adhesive extends at least partially up said sides.

22. The assembly as in claim 11, in which said adhesive laterally surrounds each of said pedestals and is interposed between said semiconductor die and said surface, has a thickness substantially equal to said pedestal height, and therefore contacts and adheres to each of said semiconductor die and said leadframe.

23. The assembly as in claim 22, in which said semiconductor die includes a top surface including circuitry thereon, an opposed bottom surface contacting said adhesive and said pedestals and facing said leadframe, and sides, and said adhesive extends at least partially up said sides.

24. The assembly as in claim 22, in which said adhesive is characterized as being void-free between said semiconductor die and said surface.
